(19) United States
(12) Patent Application Publication
(10) Pub. No.: US 2010/0248499 A1
(43) Pub. Date: Sep. 30, 2010

(54) Enhanced efficiency growth processes based on rapid thermal processing of gallium nitride films

(76) Inventors: Scott M. Zimmerman, Basking Ridge, NJ (US); Karl W. Beeson, Princeton, NJ (US); William R. Livesay, San Diego, CA (US)

Correspondence Address: William Propp, Esq.;Goldeneye, Inc., Suite 233, 9747 Businesspark Avenue, San Diego, CA, 92131, US

(21) Appl. No.: 12/657,219

(22) Filed: Jan. 15, 2010

Related U.S. Application Data
(60) Provisional application No. 61/205,329, filed on Jan. 16, 2009.

(51) Int. Cl. H01L 21/26

(52) U.S. Cl. 438/796; 257/E21.328

(57) ABSTRACT

Rapid thermal processing of freestanding gallium nitride wafers is used to form semiconductor devices. This high speed process is enabled by the low thermal inertia of the growth substrate and the use of a low thermal inertia susceptor. The use of a low thermal inertia susceptor consisting of, but not limited to, silicon carbide, silicon carbide coated graphite, and/or other platen materials. Infrared (IR) heating is a preferred approach for increasing the temperature of the freestanding gallium nitride films via the susceptor but Radio Frequency (RF) and other methods are also approaches.

### REFERENCE TO PRIOR APPLICATION

This application claims the benefit of U.S. Provisional Patent Application Ser. No. 61/205,329, which was filed on Jan. 16, 2009, which is herein incorporated by reference.

### BACKGROUND OF THE INVENTION

The quality of semiconductor devices is determined by the growth methods and the apparatus used to manufacture them. In all cases, tradeoffs are made between crystal quality, throughput, and growth conditions. Nitrides have become increasingly important for electronic and opto-electronic applications. Semiconductor devices rely on precise control of not only the composition of its layers but also the interfaces between the layers. A variety of techniques have been investigated for the growth of nitrides including but not limited to MBE, HVPE, MOCVD, and HPHT. MOCVD has become the preferred method because it offers the best compromise between the control of layer thickness and throughput.

The quality of semiconductor devices is determined by the growth methods and the apparatus used to manufacture them. In all cases, tradeoffs are made between crystal quality, throughput, and growth conditions. Nitrides have become increasingly important for electronic and opto-electronic applications. Semiconductor devices rely on precise control of not only the composition of its layers but also the interfaces between the layers. A variety of techniques have been investigated for the growth of nitrides including but not limited to MBE, HVPE, MOCVD, and HPHT. MOCVD has become the preferred method because it offers the best compromise between the control of layer thickness and throughput.

Several companies offer large multi-wafer MOCVD reactors. In these reactors, 20 or more sapphire wafers (alternate growth substrates such as silicon carbide and others have also been demonstrated) are mounted on a large circular platen, which is rotated at very high rpms. Various showerhead and process gas manifold designs are used to deliver the organometallics and process gases to the surface of the sapphire wafer. The high rotational speed is required for uniformity due to the large number of wafers typically processed. In addition, the platen must be uniformly heated to over 1000° C. and transfer this heat to the wafers rapidly and uniformly.

The tradeoff for these large multi-wafer MOCVD reactors, however, is that significant thermal inertia is created using such a large platen, which increases the thermal time constant of the system. In addition, the relatively thick sapphire wafer (growth substrate) further thermally isolates the growth surface from the heating source and adds its own heat inertia, which limits the rates at which temperature and growth conditions can be changed. These rotating platen MOCVD reactors are prevalent because they provide the most reasonable compromise between layer control and throughput. However, using this approach, a typical growth cycle of up to 8 hours is required to grow a standard nitride LED epitaxial layer. To achieve high production rates, manufacturers increase the number of wafers grown in a single batch and increase the number of machines running.

In order to grow very high efficiency devices, it is important to grow high quality layers but it is equally important to control the interfaces between these layers. This is especially important in the case of multiple quantum wells used in a variety of electronic and opto-electronic devices. The thermal inertia of the platen and growth substrate and large volume of the reactor limits how quickly the temperature and process gases can be changed at the growth surface for the larger reactors. Typically, a quantum well for a blue LED would consist of alternating layers of InGaN and GaN. These layers are typically 30 angstroms to 100 angstroms thick. InGaN growth occurs at a lower temperature and using different process gases than the GaN layer. Growth rates are on the order of 100 angstroms per minute. There can be over 100° C. temperature difference between the InGaN and GaN growth conditions. This temperature difference leads to the need for very rapid temperature shifts and gas changes in the reactor. Since a typical LED consists of a number of other layers, all with different process conditions, the transient thermal response of the growth surface becomes a critical parameter in how well both the layers and interfaces are defined. Existing reactor designs tend to create poorly defined structures with indeterminate interfaces, which degrade overall device performance. The need exists for improved methods and apparatus, which can more accurately grow nitride devices.

One approach is to use different reactors for different parts of the epitaxial layers. HVPE grown templates (GaN on Sapphire, etc.) are used to eliminate the need to grow the n or p doped contact layer, decreasing the number of layers which must be grown in the MOCVD reactor. This approach eliminates a significant amount of deposition time, however, slower ramp rates must typically be used to prevent cracking due to the bimorph nature of the sapphire/GaN template. This slower ramp rate is true during ramp up and during the rapid temperature changes required during the growth of the MQWs and other layers. To prevent cracking, slow ramp rates are required which adversely affects the ability to define definite interfaces between the layers. The purpose of this invention is to disclose processes, methods and articles, which overcome these deficiencies.

Some of the first MOCVD reactors were based on non-rotating approaches. Both horizontal and vertical configurations were developed. As sapphire wafers began to become the growth substrate of choice and increasing throughput was required to reduce the cost of devices, large multi-wafer rotating platen reactors have evolved. It is the intent of this invention to disclose process, method, and articles which match or exceed the throughput of high thermal inertia, large gas volume reactors based not on increasing wafer area but based on reducing cycle time. In addition, the use of low thermal inertia platens and growth substrates provides the added benefit of improved device structure, especially with regard to interfaces between layers.

In particular, the use of photo-assisted and IR-assisted heating techniques are preferred. This invention will disclose a susceptor free approach based on direct heating of the freestanding nitride foils which not only radically reduces the thermal time constant of the system but also enhances decomposition of the organometallics and process gases in close proximity to the substrate. IR-assisted MOCVD is also a preferred embodiment of this invention.

The disclosed technique takes advantage of the unique benefit that freestanding flexible GaN foils provide. Unlike non-native growth substrates, native nitride substrates enhance crystal growth quality but also more effectively control stresses. In present methods based on non-native substrates such as sapphire and SiC there are inherent thermal and lattice mismatches which cannot be eliminated. By using flexible native GaN foils, stresses can be reduced during regrowth processes. Thin freestanding nitride foils are also unique relative to bulk wafers which are typically diced from thicker GaN boules. Diced wafers suffer from dicing and polishing defects including variable miscut angles but diced wafers also are not flexible and cannot compensate for subsequent growths. In particular, thin foils have been demonstrated to exhibit significantly different lattice and refractive indexes (measured by HRXRD (high resolution x-ray diffraction) and prism coupled metrology) than bulk, template or even wafer bonded laser lifted off layers. As such, subsequent growths on freestanding nitride foils both epitaxially and non-epitaxially are unique and novel relative to any other existing present nitride form. This invention takes advantage of these unique and novel aspects of thin nitride foils in new and novel deposition equipment, epitaxial growth processes, and the resulting devices.

### SUMMARY OF THE INVENTION

This invention discloses the use of rapid thermal processing of freestanding gallium nitride wafers for forming semiconductor devices. These freestanding gallium nitride wafers are preferably 20 to 150 microns thick. Even more preferably, these freestanding gallium nitride wafers are 30 to 70 microns thick. By using these freestanding gallium nitride wafers, rather than gallium nitride on a non-native growth substrate, it is possible to load, ramp up, grow, ramp down and unload a typically MQW LED in less than one hour. This high speed process is enabled by the low thermal inertia of the growth substrate and the use of a low thermal inertia susceptor. The process and use of a low thermal inertia susceptor used in conjunction with the freestanding gallium nitride wafers is an embodiment of this invention. The freestanding gallium nitride wafers eliminate the bimorph issues associated with template approaches, reduce the thermal inertia of the growth substrate, and provide for a contact/current spreading layer for the device being grown. Alternately, freestanding gallium nitride layers with alternate doping, insulative, doping profiles within the freestanding gallium nitride layer, surface features, and/or alloys of nitrides can be used. A preferred embodiment is a 30 micron thick HVPE grown silicon doped gallium nitride freestanding film at least 1 cm×1 cm in area with at least one as grown surface which is epitaxial layer ready. Additionally, this freestanding film would exhibit an alpha less than 1 cm⁻¹ from 450 nm to 700 nm. Surface extraction elements on at least one surface are also included as an embodiment of this invention.

A low thermal inertia susceptor can be used consisting of, but not limited to, silicon carbide, silicon carbide coated graphite, and/or other platen materials as known in the art is disclosed. Infrared (IR) heating is a preferred approach for increasing the temperature of the freestanding gallium nitride films via the susceptor, but Radio Frequency (RF) and other methods as known in the art are also approaches. Unlike sapphire and template growth substrates, the freestanding gallium nitride wafers provide a much closer CTE match to layers being grown. The thermal conductivity of the freestanding gallium nitride wafers approaches 200 W/m/K versus 40 W/m/K for sapphire. The higher thermal conductivity and decreased thickness of the freestanding gallium nitride wafers allow for rapid thermal changes to occur. This higher thermal conductivity and decreased thickness of the freestanding gallium nitride wafers coupled with the use of a low thermal inertia susceptor and IR heating lamps allows for very precise and rapid temperature changes in the reactor. Even more preferred is the direct heating of the substrate via heating lamps either based on matching the absorption characteristics of the substrate and lamps or with the addition of an absorber layer directly on the substrate. Unlike the typical general purpose MOCVD reactor, this design is optimized for the rapid growth of the MQWs, barrier layers, and p contact layers as seen in a typical LED device. The overall total thickness of these layers is typically less than 1 micron. This design/process is also optimized for control growth condition at the interfaces between layers. Because very rapid thermal changes can be created via the heating from the IR lamps and the cooling via the process gases of the low thermal inertia susceptor and growth substrates, abrupt, ramped, and graded interfaces can be produced. Growth interruptions can also be more effectively implemented based on the reduced thermal time constant in the reactor. In this approach, throughput is gained via the nearly 100% utilization of the freestanding nitride layers, increased packing density of the freestanding nitride layers and, most importantly, reduced cycle time of the process. As stated earlier, this approach reduces the amount of time in the MOVCD reactor by up to a factor of 10.

### BRIEF DESCRIPTION OF THE DRAWINGS

FIG. 1 depicts a side view of a prior art nitride LED epitaxial layer structure.

FIG. 2A depicts a side view of a large multi-wafer rotating MOCVD platen of the prior art. FIG. 2B depicts a top view of a large multi-wafer rotating MOCVD platen of the prior art.

FIG. 3 depicts a side view of a freestanding gallium nitride wafer of the present invention.

FIG. 4 depicts a side view of a low thermal inertia reactor for use with freestanding gallium nitride wafers of the present invention.

FIG. 5 depicts a side view of a freestanding gallium nitride wafer with an LED epitaxial layer grown on one side of the present invention.

FIG. 6 depicts a side view of a freestanding gallium nitride wafer with LED epitaxial layer grown on both sides of the present invention.

FIG. 7A depicts a top view of a low thermal inertia susceptor for holding freestanding gallium nitride wafers of the present invention. FIG. 7B depicts a side view of a low thermal inertia susceptor for holding freestanding gallium nitride wafers of the present invention.

FIG. 8 depicts a top view of at least one freestanding foil mounted on a wire within the reactor

### DETAILED DESCRIPTION OF THE INVENTION

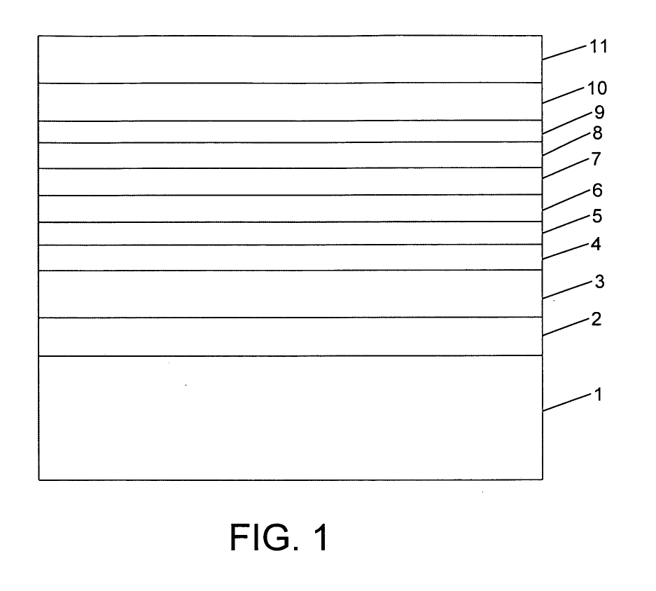

FIG. 1 depicts a typical MQW light emitting diode (LED) epitaxial layer structure grown on sapphire wafer 1. A nucleation layer 2 is used to initiate growth of the nitride device. This layer is critical due to the mismatch in lattice constants between the nitride layers and the sapphire wafer 1. After nucleation, a relatively thick n doped GaN layer 3 is typically grown. Thickness ranges from less than 1 micron to over 100 microns. The n doped GaN layer 3 is typically thicker than the other layers to enhance current spreading and to improve crystal quality. The thicker this layer is, the lower the dislocation defects for the material. However, in the prior art the thicker this layer, the larger the bowing of the bimorph wafer due to the coefficient of thermal expansion (CTE) mismatch between the nitride layers and sapphire wafer 1. This can be improved by using alternate growth substrates such as silicon carbide or other wafer materials, but in all cases the use of a non-native growth substrate leads to bowing at some level, either at room temperature or at growth temperatures. Non-native growth substrates also are more susceptible to thermal shock issues associated with the rapid thermal changes needed to create high quality interfaces between layers.

Quantum well layers 4, 5, 6, 7, 8 and 9 are grown next and typically are alternating angstrom-thick layers of different nitride alloys of indium, aluminum, or some other dilute nitride. Reactor conditions both from a thermal and gaseous atmosphere standpoint must be rapidly changed in order to precisely create these layers. This is very difficult in conventional large reactors due to this large thermal mass, large process areas, and large wafers being processed. Hysteresis, load factor, and memory describe the effect of past operating conditions affecting subsequent growth conditions.

Silicon doping is used to create n type material in n doped GaN layer 3. Some residual levels of the silicon are then present throughout the growth cycle. This residual silicon becomes problematic for barrier layer 10 and p doped GaN layer 11 which typically are magnesium doped. High quality p type material is difficult to grow in nitrides in any case but silicon tends to compete with magnesium, decreasing the quality of the p doped layers. The large volume and amount of doped area (number of wafers×size of wafer) in a typical MOCVD reactor also contributes to this problem. By using small freestanding gallium nitride substrates, which are silicon doped as disclosed in this invention, this problem can be reduced. The method disclosed herein may be used to create ultraviolet emitting LEDs. In the case of UV devices, AlGaN and AlGaInN alloys are used, which are equally difficult to process. The method disclosed herein also enhances the processing of these materials. This invention is applicable to all nitride based devices and hybrids including but not limited to alloys of zinc oxide, selenides, and sulfides.

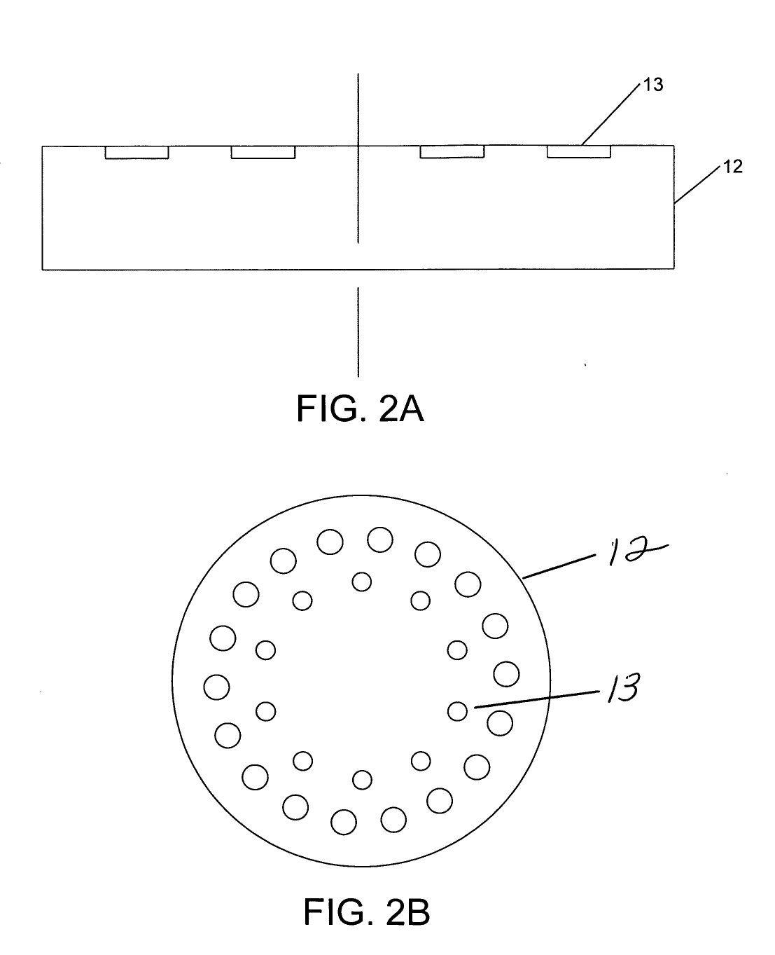

FIGS. 2A and 2B depict a typical multi-wafer rotating MOCVD platen 12. To achieve uniform process conditions, across all wafers, large rotation platens are used. The industry has concluded that the only way to achieve uniformity is to vary the position of the wafers inside the platen. These platens are typically silicon carbide coated graphite. Over 30 wafer platens are commercially available and rotational speeds greater than 1000 rpm may be used. To accommodate the large number of wafers, large IR heaters and RF heaters are used. These large heaters are used to provide the necessary heating of the platen 12. Wafers fit into pockets 13 which may be stationary or planetary in nature. The pockets 13 are typically arranged as two concentric rings and, even with planetary motion, significant differences can be seen in wafers of the outer and inner rings. Platen 12 must exhibit sufficient thickness to not only support the wafers, but also provide a deep enough recess such that the wafers do not eject from the pockets 13 during high speed rotation. The use of clips and other hold down mechanisms are possible, but the high rotational speeds and high growth temperatures can also create problems for the clips, which, if they fly off, can damage the reactor itself. In addition, the platen must exhibit sufficient thermal spreading to equalize any non-uniformity in the heating source. However, the platen then adds its own thermal inertia, which becomes especially problematic in dynamic heating situations such as are experienced during rapid thermal changes required to growth the MQWs. The need therefore exists for methods whereby more uniform heating can be created without the need for a thick platen exhibiting large thermal inertia.

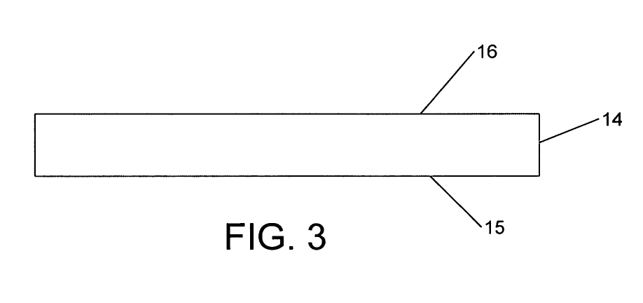

FIG. 3 depicts a freestanding gallium nitride wafer 14. The freestanding gallium nitride wafer 14 should preferably have a thickness greater than 20 microns and less than 150 microns. Even more preferably, freestanding gallium nitride wafer 14 should have a thickness greater than 30 microns and less than 70 microns. Even more preferably, freestanding gallium nitride wafer 14 is silicon doped n type gallium nitride with a dopant concentration greater than 10 18, and, most preferably freestanding gallium nitride wafer 14 exhibits an optical absorption coefficient alpha less than 1 cm⁻¹ throughout the visible spectrum. The area of the freestanding gallium nitride wafer is preferred between 1 sq. mm to 1 sq. inch. Laser and/or etching means can create mounting holes or features for alignment and mounting.

The use of nitride alloys containing but not limited to aluminum, indium, and/or other dilute nitrides as known in the art are also disclosed. As such AlN, AlGaN, GaN, AlInGaN, InGaN, as well as dilute nitride containing As, P, and other elements are included as embodiments of this invention. The dopant and alpha used are linked to the particular alloy. As an example, 20% InGaN will not have an alpha less than 1 cm⁻¹ throughout the visible spectrum due to the band-edge location as known in the art. The alpha restriction would therefore be adjusted according to the particular alloy used in a manner as known in the art. Alpha is especially important with regard to LEDs due to absorption losses effecting output efficiency.

The top surface 16 on freestanding gallium nitride wafer 14 can be as grown and/or epitaxial ready. It may also be textured or patterned to allow for crystal quality enhancements such as lateral overgrowth as known in the art. The patterning of embedded extraction elements and photonic lattices enhances efficiency and/or impart directionality. Bottom surface 15 of freestanding gallium nitride wafer 14 may also be patterned or textured in a manner similar to top surface 16 for similar reasons. Top surface 16 and bottom surface 15 may also be textured to modify stress profiles in the freestanding gallium nitride wafer 14. Sacrificial coatings can be used including AlN, ZnO, and other high temperature coatings either over the entire surface or over a portion of either surface to prevent degradation or modification of the freestanding gallium nitride wafer 14 is also disclosed. Pre-scribing (prior to growing MQWs) using etching, laser, and/or mechanical means of top surface 16 and/or bottom surface 15 can facilitate die segmentation, cleaving, isolation (optical and/or electrical) and creating MEMS structures. Even more preferred is the use of in-situ etching including but not limited to HCL etching and photo-assisted etching prior to, during or after epitaxial growth. In addition, the growth of nanostructures on the freestanding gallium nitride wafer 14 during or subsequent to device growth is also an embodiment of this invention. In particular, the formation of the textured or nanowire structure of alloys of ZnO or other transparent conductive oxides have been demonstrated as effective extraction elements and are embodiments of this invention.

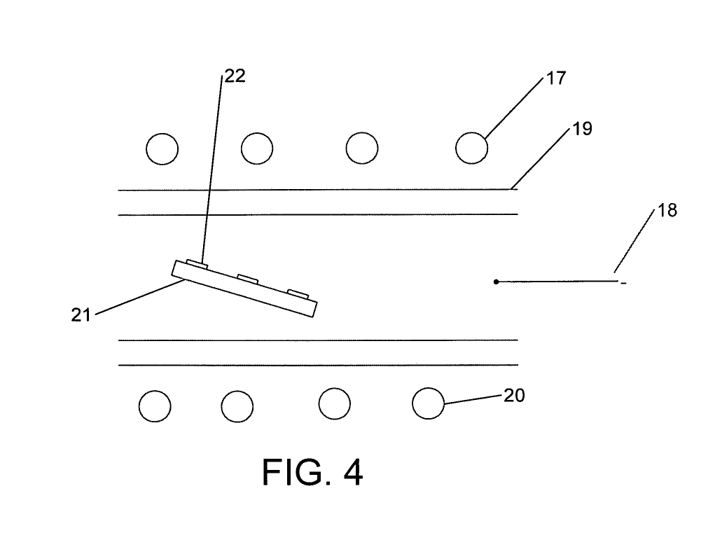

FIG. 4 depicts a low inertia flow through reactor. A quartz envelope 19 is used to contain process gas flow 18, low thermal inertia susceptor 21, and freestanding gallium nitride wafers 22. Heating sources 17 and 20 may consist of, but are not limited to, IR lamps and/or RF heaters. Using freestanding gallium nitride wafers 22 and this rapid thermal processing approach, process cycle time can be reduced to under one hour. Even more preferably, process cycle time can be reduced to under 30 minutes. In this manner, the throughput of the large multi-wafer reactors can be matched or exceeded. In addition, higher quality devices can be manufactured based on improved interface controls. Orientation of the low thermal inertia susceptor 21 within process gas flow 18, as known in the art to enhance uniformity, is an embodiment of this invention. Alternately, the use of low thermal inertia susceptor 21 allows exposure of the majority of both sides of the freestanding gallium nitride wafers 22. The freestanding gallium nitride wafers 22 are oriented such that uniform illumination and the use of electromagnetic directing means insures uniform heating of the freestanding gallium nitride wafers 22. The low thermal inertia susceptor 21 may consist of only a mounting wire or clip to further reduce the thermal time constant of the system. The use of laser and etching techniques to form mounting and alignment elements directly in the freestanding gallium nitride wafer 22 is a preferred embodiment due to reduced thermal mass and ease of mounting within the reactor.

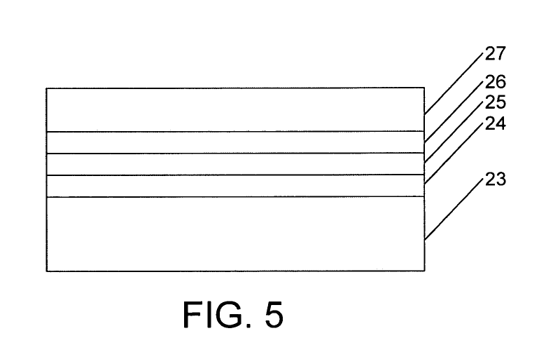

FIG. 5 depicts a single quantum well (SQW) LED grown on n doped freestanding gallium nitride wafer 23. The SQW is formed by InGan layer 24 and GaN layer 25. Barrier layer 26 consists of p doped AlGaN and p doped contact layer 27 complete the LED epitaxial layer structure. Ohmic contacts can be subsequently formed either via metallization or degenerate transparent conductive oxides, as known in the art. Critical to the performance of this LED is the control of the thickness and interfaces forming the SQW. This freestanding GaN foil and small size allows rapid temperature changes while also assuring uniformity.

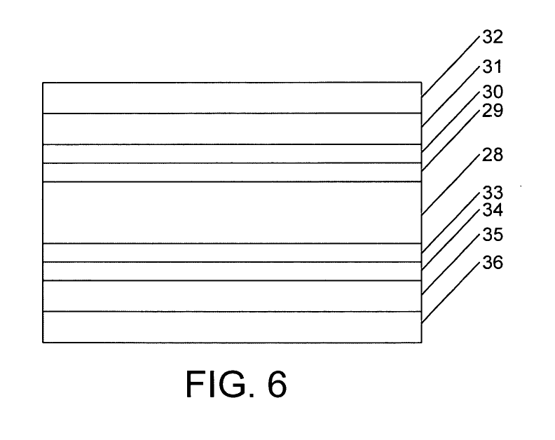

FIG. 6 depicts a LED with SQWs grown on both sides of the freestanding gallium nitride wafer 28. This LED can be realized using a susceptor, which contains openings to both sides of the freestanding gallium nitrides wafer 28, as discussed previously. SQW pair 29 and 30, barrier layer 31 and p layer 32 are formed on the top surface of freestanding gallium nitride wafer 28 while SQW pair 33 and 34, barrier layer 35 and p layer 36 are formed on the bottom surface of freestanding gallium nitride wafer 28.

These layers may be substantially identical or different as required. Different growth conditions either based on gas flows and/or temperature can be used to create different thickness and/or composition between the top and bottom structures grown on freestanding gallium nitride wafer 28. In this manner, novel dual sided devices including, but not limited to, broadband emitters, solar cells, piezoelectric devices, and MEMS can be formed in a single growth step. In particular, the balancing of stresses using this dual sided approach is an embodiment of this invention. This lowers the stress in the GaN and improves resulting device properties. It has been found that using these freestanding GaN substrates (as described herein), the stress is substantially reduced at growth temperature. The stress is sufficiently reduced to allow the growth of laser diodes. Even more preferably, low indium content InGaN outer layers can be formed on freestanding gallium nitride wafer 28 for use in visible LED laser diodes.

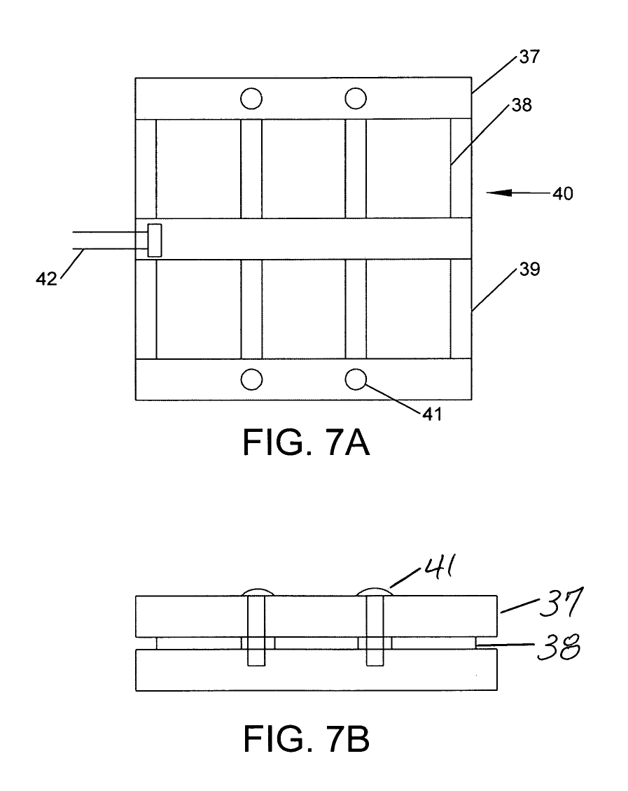

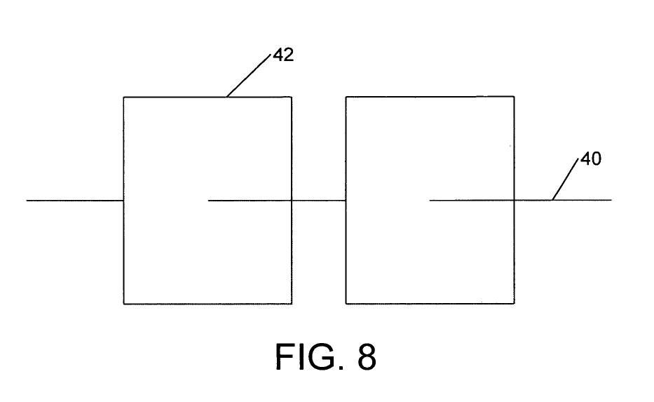

FIGS. 7A and 7B and 8 depict a low thermal inertia susceptor based on a relatively thin silicon carbide plate 39 to which multiple freestanding gallium nitride wafers 38 are mounted down via clamps 37 and bolts 41. Alternate mounting directions and clamping means are also embodiments of this invention. More preferably, the low thermal inertia susceptor is configured and mounted such that gas flow 40 is uniformly dispersed across the freestanding gallium nitride wafers 38. Temperature feedback 42 may consist of thermocouple, foil thermocouple, pyrometer, as well as other temperature sensing means, as known in the art. A preferred embodiment is the use of at least one light source which emits near the band edge of the multiple freestanding gallium nitride wafers 38 mounted such that a substantial portion of the emitted light passes through at least one of the multiple freestanding gallium nitride wafers 38. The transmitted light is detected by a detector which senses change in intensity of either a single wavelength or measures the intensity changes in range of wavelengths above and below the bandedge of at least one of the multiple freestanding gallium nitride wafers 38. The bandedge of gallium nitride or any material is temperature sensitive. While the use of reflected light has been used in the past to measure directly the growth temperature of the surface of the substrates, this invention discloses the use of transmitted light in combination with thin transparent substrates which not only increase the accuracy of the temperature measurement but also is unique to the thin foils used in this invention. The heating elements such as IR lamps are aligned with the freestanding gallium nitride wafers 38 to create uniform heating. IR lamps are a preferred embodiment, but lamps containing shorter wavelengths such as mercury and xenon high powered lamps are also disclosed. The use of separate heating zones allows for preheating of process gases and metallorganic precursors. In particular the use of photo lamps which are filtered allows for heating of the process gases and metallorganic precursors with or without photochemical effects. Even more preferably, IR lamps filtered can substantially reduce photochemical processes due to high energy photons such that the majority of the decomposition occurs due to the substrate. Alternately, the use of photochemical etching for both chamber wall cleaning and etching of the growth substrate is also disclosed. In particular the use of gaseous etchants such as, but not limited to, HCL and other etchants to clean build up of particles and deposited layers on the quartz wall. This cleaning technique is critical to prevent changes in the amount of light which is incident on the freestanding gallium nitride wafer 38 due to absorption at the walls of the reactor. In addition, gaseous etchants within gas flow 40 can etch freestanding gallium nitride wafer 38 for removal of surface contaminants in-situ, improve subsequent epitaxial growth, improve electrical properties such as leakage and form extraction elements. In particular, light extraction elements can be formed using pre and post photochemical assisted etching of the freestanding gallium nitride wafer 38. Also disclosed is the use of non-uniform heating to create devices, which have variable properties such as output wavelength. This approach can be used to create LEDs, which emit a number of wavelengths simultaneously.

The use of low thermal inertia (heat capacity) components in the reactor to effect rapid changes in temperature is an embodiment of this invention. By keeping the volume of the reactor to a minimum (which is enabled by the relative small samples being processed) the volume and therefore mass of the process gas is minimized thereby keeping the heat capacity (thermal inertia) of the gas to a minimum. The susceptor's heat capacity is preferably under 14 joules/° C. and more preferably under 0.6 joules/° C. The freestanding nitride and/or GaN heat capacity (thermal inertia) is preferably under 0.4 joules/° C. and more preferably under 0.2 joules/° C. and most preferably under 0.04 joules/° C. Shown in FIG. 8 is a means of holding the freestanding GaN in the reactor without a susceptor. Low heat capacity wire 40 (molybdenum, tungsten, carbon fiber, etc) is threaded through the freestanding nitride foils 42 and suspends the foils in the reactor for processing. These low thermal inertias (heat capacities) are achieved through the use of small thin nitride foils during processing.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

What is claimed is:

1. A means of fabricating nitride semiconductor devices utilizing a rapid thermal reactor and at least one thin freestanding nitride foil.

2. The means of fabricating nitride semiconductor devices of claim 1 utilizing a rapid thermal reactor and at least one thin freestanding nitride foil wherein the thickness of said at least one freestanding nitride foil is less than 100 μm thick.

3. The means of fabricating nitride semiconductor devices of claim 1 utilizing a rapid thermal reactor and at least one thin freestanding nitride foil wherein said at least one freestanding nitride foil is Gallium nitride.

4. The means of fabricating nitride semiconductor devices of claim 1 utilizing a rapid thermal reactor and at least one thin freestanding nitride foil wherein said at least one freestanding nitride foil is Gallium nitride and is less than 100 μm thick.

5. The means of fabricating nitride semiconductor devices of claim 4 utilizing a rapid thermal reactor and at least one thin freestanding nitride foil wherein said Gallium nitride foil is greater than 1 cm2 in area but less than 1 square inch in area.

6. The means of fabricating nitride semiconductor devices of claim 4 utilizing a rapid thermal reactor and at least one thin freestanding nitride foil wherein a low thermal inertia susceptor is used to rapidly and uniformly heat and cool the freestanding nitride foil.

7. The means of fabricating nitride semiconductor devices of claim 4 utilizing a rapid thermal reactor and at least one thin freestanding nitride foil wherein no susceptor is used to heat and cool the freestanding nitride foil.
